(19) United States
(12) Patent Application Publication
(10) Pub. No.: US 2024/0229286 A9
(43) Pub. Date: Jul. 11, 2024

(54) A PROCESS TO PROTECT LIGHT METAL SUBSTRATES

(71) Applicant: CIRRUS MATERIALS SCIENCE LIMITED, Wairu Valley, Auckland (NZ)

(72) Inventors: Christopher William Goode, Snells Beach, Auckland (NZ); Fengyan Hou, Wairu Valley, Auckland (NZ)

(21) Appl. No.: 18/547,933

(22) PCT Filed: Mar. 2, 2022
(86) PCT No.: PCT/NZ2022/050024

§ 371 Date: Aug. 25, 2023

Related U.S. Application Data
(60) Provisional application No. 63/155,708, filed on Mar. 2, 2021.
(60) Provisional application No. 63/237,518, filed on Aug. 26, 2021.

(51) Int. Cl. C25D 11/16; C25D 11/10; C25D 11/30

(52) U.S. Cl. CPC C25D 11/16; C25D 11/10; C25D 11/30

(57) ABSTRACT

There is disclosed a method of placing a substrate into a controlled conductivity plasma electrolytic oxidation (PEO) bath configured for the substrate; wherein the PEO bath includes a nitrogen containing organic compound, and applying a voltage for a period of time to produce a substantially continuous nitride or nitrogen compound containing PEO layer of between about 1 to about 100 microns thick on the substrate. The substrates are preferably magnesium, titanium, or aluminium. The PEO process is preferably carried out under alkaline conditions and at voltages of less than about 160 volts.

### BACKGROUND

Anodizing is an electrolytic passivation process extensively used as a method to protect light metal substrates, such as magnesium and its alloys, aluminium and its alloys and titanium and its alloys. Anodizing typically uses an acidic bath using DC, pulsed DC, or AC current between the anode and a passive or stable cathode such as titanium on stainless steel. Anodizing of aluminium and titanium produces a regular array of pores which must be sealed to provide an environmental barrier.

Sealing the pores can include a dying step to produce a decorative coating and often uses a nickel acetate solution or boiling water. The boiling water seals the pores by hydrating and swelling the oxide. Generally protective films are thick coatings, e.g., hard anodizing on aluminium.

Alternatively, a metallic seal can be electrolytically or autocatalytically deposited in the pores such as that described in U.S. Pat. No. 10,519,562 B2.

Aniline and other conductive polymers can be anodically deposited in acidic baths and a method to seal the pores of aluminium was disclosed in U.S. Pat. No. 5,980,723 and WO 2009098326A1 with either a combination of a conductive polymer and metal oxide nano particles. Such seals produce superior corrosion resistance.

Micro Arc Oxidation (MAO) or Plasma Electrolytic Oxidation (PEO) is an electrochemical surface treatment which uses high potentials, well above 400V to electrochemically modify the naturally occurring passivate layer on light metal and their alloys, especially magnesium in commercial applications. The process uses an alkaline bath with high potentials to create discharges that modify the nature of the oxide layer which grows inward and outward from the substrate producing an adherent, hard continuous barrier layer.

MAO/PEO is frequently energy intensive and often requires toxic chemicals, such as chromic acid and fluoride to produce coatings.

The introduction of nitrogen containing organic compounds in an alkaline low voltage PEO bath is unknown and the polymerisation of the polymer on the PEO surface which is modified by the arc to create a coating combining silicates, oxides, nitrides, and polymers is unknown.

There is a need for a process that directly protects light metal substrates with a thin film deposited from a benign chemistry using low energy.

### SUMMARY

According to aspects illustrated herein, a method for producing a coating on magnesium, aluminium and titanium substrates is provided. One feature of the aspects is placing the substrate in a controlled conductivity plasma electrolytic oxidation (PEO) bath of composition that depends on the substrate and includes a nitrogen containing organic molecule. Voltage is applied for a period of time to produce a substantially continuous nitride or nitrogen compound containing PEO layer, about 1 to 100 microns thick, on the substrate. In one embodiment the substrate is pre-treated.

In one embodiment the PEO bath is alkaline. In one embodiment the alkaline PEO bath comprises one or more hydroxides. In a further embodiment the PEO bath may further comprise one or more metal salts, monomers of conductive polymers or other nitrogen containing organic compounds, surfactants, and oxidisers, or combinations thereof.

In one embodiment the nitrogen containing organic compound is a monomer, which upon polymerisation forms a conductive polymer containing nitrogen.

In one embodiment the PEO bath includes a surfactant. In one embodiment the surfactant is SDS.

In one embodiment the period of time to apply the voltage is up to about 1000 seconds.

In one embodiment the conductivity of the PEO bath is controlled to limit the micro arc generation voltage during PEO treatment to below about 160V at a current density of less than about 10A/dm².

In one embodiment a high molecular weight organic salt component of the bath which is adsorbed on the substrate controls the conductivity of the PEO process.

In another aspect, there is provided a PEO-treated substrate produced according to the methods defined herein, the PEO-treated substrate comprising a substantially continuous nitride or nitrogen compound containing layer of between about 1 to 100 microns thick. In one embodiment the PEO substrate comprises a substantially continuous nitride containing layer.

In another aspect there is a provided a PEO-treated substrate having a substantially continuous nitride or nitrogen compound containing layer of between about 1 to about100 microns thick, formed by micro arc generation during PEO at below about 160V and at a current density of less than about 10A/dm².

In one embodiment the substrate is aluminium, titanium or magnesium.

### BRIEF DESCRIPTION OF DRAWINGS

FIG. 1 is a flow diagram of a method for producing a coating on magnesium, aluminium or titanium.

FIG. 2 is an SEM image of a PEO coating produced according to one prior art method.

FIG. 3 is an optical microscope image and an SEM image of a coating produced in a bath without a conductive polymer component.

FIG. 4 is an optical microscope image and SEM image of a coating produced in a bath with a conductive polymer coating.

FIG. 5(a) is an XRD analysis of a coating with aniline and FIG. 5(b) is an XRD analysis of a coating without a conductive polymer.

FIG. 6 selected DOE result data for first DOE analysis

FIG. 7 selected result data for Al and Ti substrates

FIG. 8 shows SEM images of coatings produced on Al substrates with and without a conductive polymer component.

FIG. 9 shows SEM images and XPS analysis of coatings produced on Ti substrates with and without a conductive polymer component.

### DETAILED DESCRIPTION

The following description sets forth numerous exemplary configurations, parameters, and the like. It should be recognised, however, that such description is not intended as a limitation on the scope of the present invention but is instead provided as a description of exemplary embodiments.

### Definitions

In each instance herein, in descriptions, embodiments, and examples of the present invention, the terms “comprising”, “including”, etc., are to be read expansively, without limitation. Thus, unless the context clearly requires otherwise, throughout the description and the claims, the words “comprise”, “comprising”, and the like are to be construed in an inclusive sense as to opposed to an exclusive sense, that is to say in the sense of “including but not limited to”.

The term “about” as used herein means within 20%, more preferably within 10%, and most preferably still within 5% of a given value or range. Alternatively, the term “about” means within a log (i.e., an order of magnitude) preferably within a factor of two of a given value.

The term “nitrogen containing organic compound” means an organic compound having one or more nitrogen atoms. Suitable nitrogen containing organic compounds include but are not limited to primary, secondary, or tertiary nitrogen atoms, such as aniline, pyrrole and triethanolamine. Suitable nitrogen containing organic compounds include nitrogen containing monomers which upon polymerisation form a nitrogen containing conductive polymer.

The term “substantially continuous nitride containing layer” means a layer comprising one or more nitride compounds distributed across at least about 95% of a substrate surface. It is to be appreciated that the layer may be distributed across at least about 96%, at least about 97%, at least about 98%, at least about 99%, or across 100% of the substrate surface.

It is to be appreciated that while nitride containing compounds are specifically mentioned in the PEO layer that other nitrogen containing compounds are not excluded. It is to be further appreciated that the anodized layer may also include oxides of the substrate metal or oxynitrides of the substrate metal and/or silicates and these are formed as part of the PEO process.

Examples described herein provide a process to develop oxide, nitride, silicate, and polymer coatings on magnesium, aluminium, or titanium substrates. As noted above, previous attempts to coat these metals using a PEO process have failed or are undesirable due to a variety of reasons. For example, previous methods may use processes generally involving toxic chemicals, use a PEO process that is energy intensive, and be relatively expensive.

The present disclosure provides a process to develop a coating on a magnesium, titanium or aluminium alloy substrate that eliminates the use of toxic chemicals, is less energy intensive, and relatively cheaper than previous methods. The substrate may be pre-treated, for example, the process may include a step of mechanically or chemically polishing and/or degreasing a substrate. A film of between about 1 and about 100 microns can be deposited by plasma electrolytic oxidation on the substrate from a PEO bath comprising sodium hydroxide or potassium hydroxide, disodium metasilicate, sodium citrate, hydrogen peroxide, a surfactant, a monomer of a conductive polymer, nitrogen containing organic compounds, other additives to produce a continuous anodized layer, or any combination thereof.

The PEO layer so produced may be conductive and may form a substrate for a further electrodeposited, autocatalytically deposited, anodically deposited, e-coated, or painted coating as described in application U.S. application Ser. No. 63/015411, included herein in its entirety by reference.

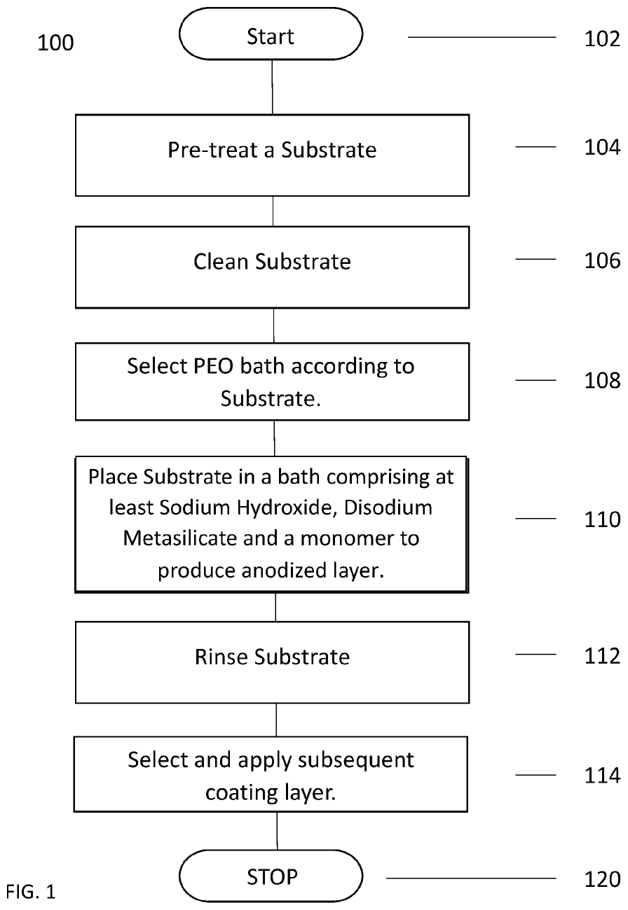

FIG. 1 illustrates an example method 100 for producing a PEO layer containing nitrides and polymers on magnesium. The method 100 may be performed by various equipment or tools in a processing facility under the control of a processor or controller.

At block 102, the method 100 begins. At block 104, the method 100 may pre-treat a substrate. In one embodiment, the substrate may be a magnesium substrate that may be a wrought or cast alloy of magnesium. Examples of such magnesium substrates may include AZ80 or ZK60 or any suitable magnesium alloy. In one embodiment the substrate may be any suitable magnesium alloy. In an alternative embodiment the substrate may be an aluminium substrate. Examples of aluminium substrates include 2000, 3000, 4000, 5000, 6000, and 7000 series aluminium alloys. In an alternative embodiment the substrate may be Titanium substrate. Examples of Titanium substrates include Ti-T1, Ti-T2, etc. or any suitable Titanium alloy.

In one embodiment, the pre-treatment may include one or more processes. The pre-treatment process may include chemically treating the substrate in a concentrated nitric acid bath or dilute sulphuric acid bath, mechanically roughening the substrate through emery paper, sand or bead blasting, and/or cleaning the substrate for about 3 to 15 minutes in an alkaline bath comprising of between about 10-20 grams per litre (g/L) sodium carbonate and between about 15-20 g/L sodium phosphate, between about 10-20 g/L sodium silicate, and between about 1-3 g/L commercial OP-10 surfactant at between about 60 to 80 degrees Celsius (° C.)

Mechanically roughening the surface may produce enhanced adhesion between the PEO layer and the substrate. The adhesion may be further enhanced in the presence of tensile forces produced in later deposited functional surface layers. Mechanical roughening can be accomplished by using appropriate grades of emery paper up to 1200 grit. In one embodiment, sand or bead blasting can produce an appropriate surface on which to create the PEO layer.

At block 106, the method 100 may clean the substrate. The substrate can be cleaned prior to being anodized. The substrate may be cleaned by rinsing in de-ionized (DI) water. In one embodiment, the substrate may be ultrasonically cleaned in a solution of ethanol or acetone. When the substrate is cleaned, the cleaning step should prevent the creation of any oxide layer on the surface. In other words, cleaning the substrate should not allow a new oxide layer to be created on the surface.

At block 108, the method 100 selects a PEO bath according to the nature of the substrate. For example, the composition of the PEO bath may be selected in accordance with the composition of the magnesium substrate, titanium substrate or aluminium substrate. The bath composition may be selected from between about 5-80 g/L of sodium hydroxide or between about 5-80 g/L of potassium hydroxide, between about 10-90 g/L of disodium meta silicate, between about 0-40 g/L of sodium citrate, between about 2-30 ml/L of hydrogen peroxide, between about 0.05 mM to 1 M of SDS, and between about 0.1 M and 1 M of a monomer of a conductive polymer or nitrogen containing organic compound.

In certain embodiments the monomer may be aniline, in other embodiments pyrrole, in further embodiments the monomer may be triethanolamine. In each case the monomer must contain nitrogen.

In one embodiment for a AZ80 substrate and the bath comprises of 35 g/L NaOH, 60 g/L Na₂SiO₃, 24 g/L sodium citrate, 6 mL/L of hydrogen peroxide (H₂O₂), 3.7 ml/L aniline, and 0.05 mmol/L SDS.

Here the NaOH also provides an alkaline environment which protects the magnesium (Mg) substrate and assists in the oxide reaction forming MgO. The Na₂SiO₃, which is a source of silicon, develops Mg₂SiO₄ in film. Both elements affect the conductivity of the bath and thus the peak PEO voltage with higher concentrations lowering voltage. Sodium citrate improves the reaction uniformity by adsorbing on the substrate. Aniline is the source of nitrogen for the nitriding reaction, while sodium dodecyl sulfate (SDS) is a surfactant which assists with the uniform distribution of the nitrogen containing organic compound, in this example aniline throughout the bath. Finally, H₂O₂ assists with the oxidation process improving the coating uniformity.

In another embodiment the substrate is either 6061 aluminium, other aluminium alloy, or a titanium alloy and the baths comprise 45 g/L NaOH, 60 g/L Na₂SiO₃, 24 g/L sodium citrate, 6 ml/L of hydrogen peroxide, 4.9 ml/L aniline, and 0.05 mmol/L SDS. At block 110, the method 100 places the substrate in a bath comprising at least one of: sodium hydroxide or disodium metasilicate to produce a PEO layer. In one embodiment, the PEO bath may be in a heating and/or cooling apparatus to maintain a stable solution temperature. In one embodiment, the PEO bath may include a stainless-steel counter electrode. In one embodiment, a direct current (DC) power supply may provide voltage and current to perform PEO processing. In one embodiment, a pulsed DC power supply may provide the PEO power.

In one embodiment, the PEO bath may be operated between 18° C. and 30° C. In one embodiment, the PEO bath may be maintained at a temperature of approximately 25° C.

In one embodiment, the substrate is AZ80 magnesium and a constant current PEO current may be adopted. In one embodiment, the constant current may be maintained between 0.5 and 6 amperes per square decimetre (A/dm²). In one embodiment, the current may be limited to 1 A/dm².

In an alternative embodiment, the substrate is 6061 aluminium or T1 titanium, and a constant PEO current may be adopted. In one embodiment the constant current may be maintained between about 0.5 and about 10 amperes per square decimetre (A/dm²). In one embodiment, the current may be limited to about 4 A/dm².

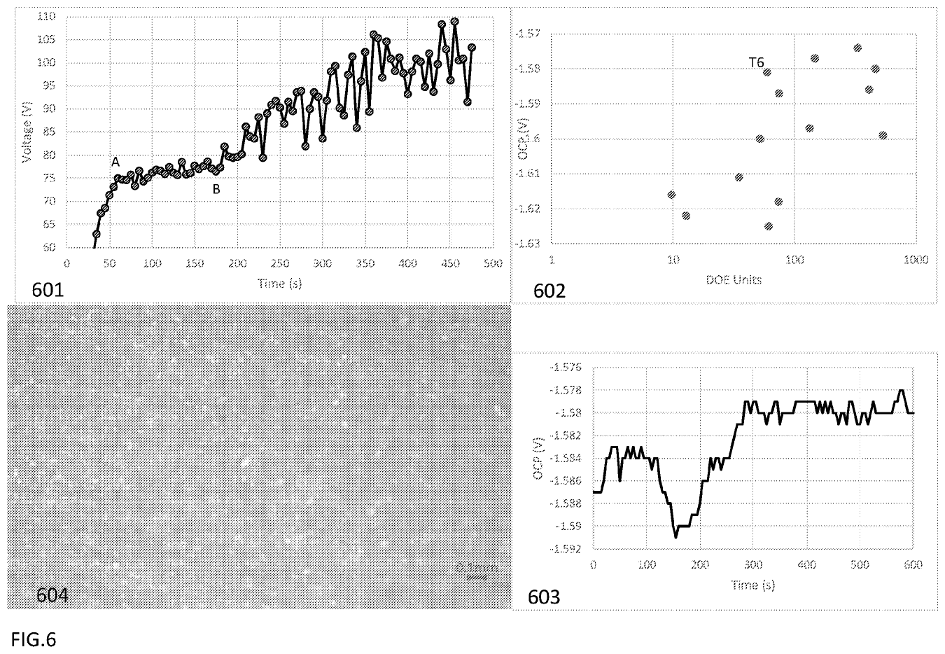

In one embodiment the PEO current density and the bath composition control the PEO voltage response curve. In one embodiment the PEO voltage response curve for a AZ80 magnesium substrate comprises three regions, FIG. 6, 601. The region from time 0 to 601 point “A’ corresponds to the initial growth of the anodic layer. In one embodiment this time is preferably less than 60 seconds. The region from 601, point A to point B corresponds to the initial arcing period where high density small arcs develop across the entire anodic surface, the length of this period is principally controlled by the bath chemistry. In one embodiment the period from point A to point B is from 60 second to 240 seconds, preferably greater than 120 seconds. The region beyond 601, point B, i.e., out to about 500 seconds corresponds to widely distributed large arcing and the average voltage is principally dependent on the coating thickness and bath composition. In one embodiment the average voltage is between 70 and 130V, between 80 and 120V, preferably less than 100V.

In one embodiment, the combination of the ionic concentration and the level of an organic agent in the PEO bath may be used to control the peak voltage. In one embodiment, the organic agent may be disodium citrate. Disodium citrate is a large molecule which is adsorbed onto the substrate surface to limit the conductivity, while both NaOH is a conductive ion that promotes conductivity.

In one embodiment the voltage at which arcing initially occurs and the current density required to sustain that voltage is a function of the dielectric strength of the principally oxide coating, the thickness of the coating and the conductivity of the PEO bath.

The thickness of the PEO film in the present disclosure may be between about 1 and about 100 microns. However, the thickness may also be between 4 and 10 microns. In one embodiment, the thickness may be between 4 and 8 microns.

PEO for 15 minutes at the above-described conditions results in a PEO film of about 6 microns.

At block 112, the method 100 includes the step of rinsing the substrate. The PEO layer of the substrate may be rinsed in DI water or ultrasonically cleaned in ethanol.

At block 114 the method 100 selects a further coating to either provide more protection to the substrate or a decorative aspect to the coating. For example, in one embodiment a further coating may comprise of electrolytically or autocatalytically deposited metal coating such as a nickel, copper, silver, cobalt, tin or alloys of these metals to provide improved corrosion resistance or other functional characteristics. In another embodiment the further coating may be an e-coat, powder coat or other polymer coating to provide a decorative aspect. In alternative embodiment a further coating may be a conductive polymer coating to improve the corrosion resistance.

At block 120 the method 100 ends.

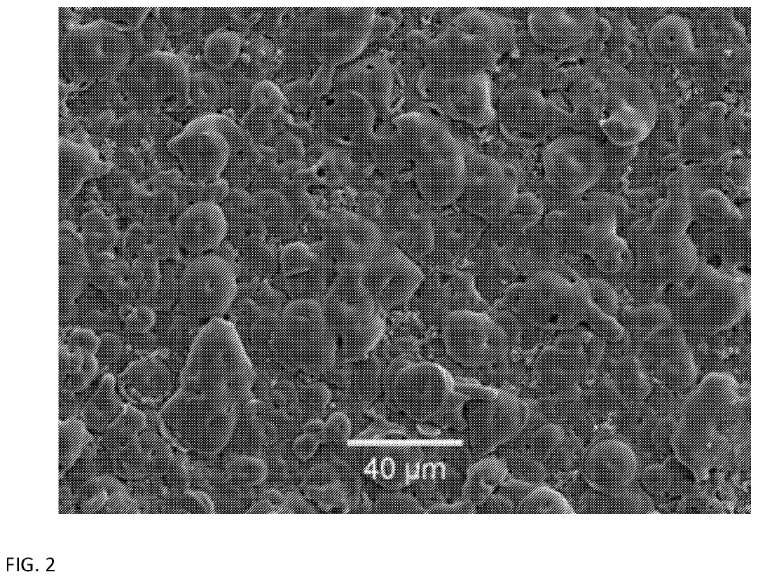

FIG. 2 shows a typical PEO surface on a magnesium alloy. The coating is continuous but exhibits cracking typical of the coating process. These cracks provide ingress for corrosion and thus only very thick coatings, requiring high energy consumption, provide sufficient protection for a substrate.

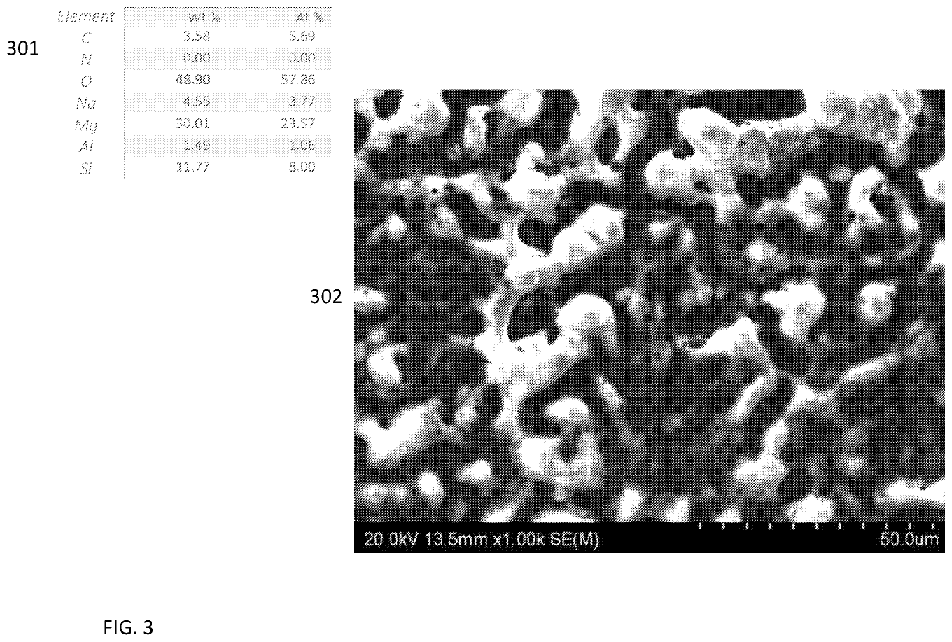

FIG. 3 shows an SEM image 302 of a coating produced from a bath comprising of 70 g/L NaOH, 60 g/L Na₂SiO₃, 12 g/L sodium citrate, and 6 mL/L H₂O₂. This is a porous conductive surface suitable for deposition of further metallic layers. The SEM/EDS analysis, 301, shows the composition of the coating. The main constituents are magnesium and oxygen, as MgO, generated by the PEO process. Silicon, as both magnesium silicate, sodium silicate and silicon dioxide, is derived from the disodium silicate that forms part of the PEO bath. Aluminium as alumina forms from the aluminium that is alloyed in the magnesium substrate. The carbon in the sample is adventitious or resulting from the breakdown of the sodium citrate in the arc.

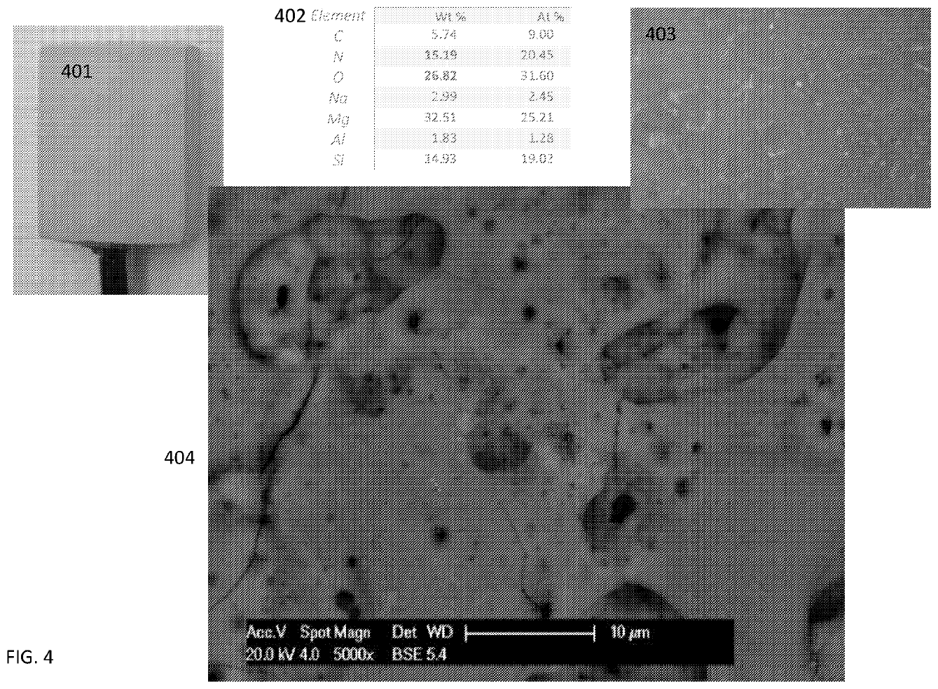

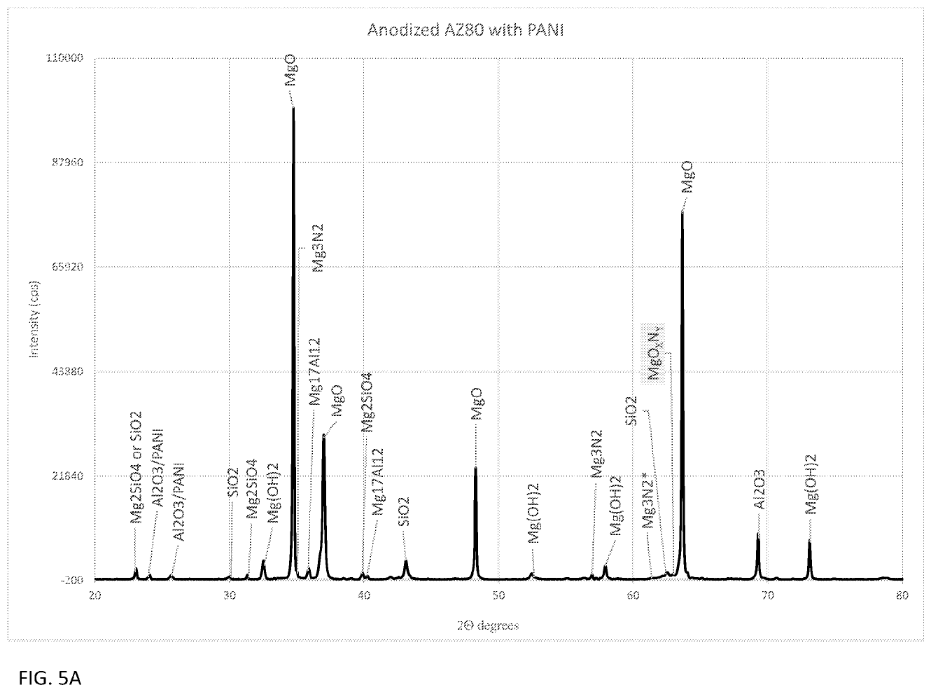

FIG. 4 shows an example of a coated Mg substrate, 401, produced according to certain aspects of this disclosure from an identical method to that of the coating in FIG. 3 (70 g/L NaOH, 60 g/L Na₂SiO₃, 12 g/L sodium citrate, and 6 mL/L of H₂O₂) with the addition of 0.2 M aniline. The associated optical microscopy image, 403, shows a uniform coating where the light areas correspond to the crystal structure of the underlying substrate. The SEM image, 404, clearly contrasts to the SEM images 302 where the microstructure is substantially uniform with limited porosity.

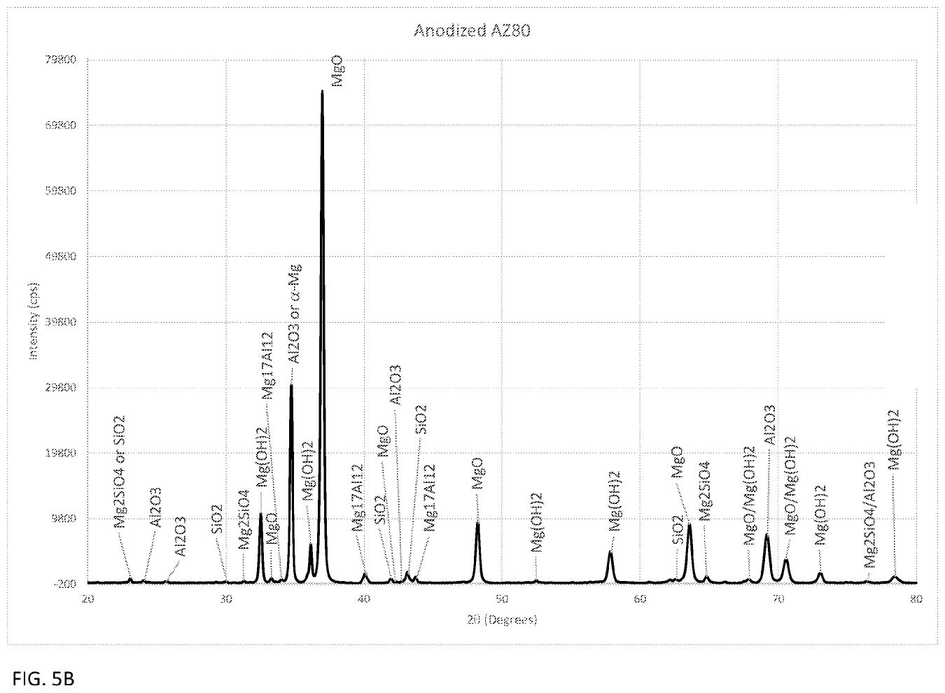

The SEM/EDS analysis in 402 shows the composition of the coating, unlike the coating in FIG. 3, the magnesium, silicon, and aluminium are at similar levels while the oxygen is significantly lower, and nitrogen is present. FIG. 5(a) shows an XRD analysis of the anodized coating with aniline according to one aspect and FIG. 5(b) shows a comparative XRD analysis of a coating without aniline from an identical bath. As may be seen the aniline enhanced coating includes XRD peaks for magnesium nitride (Mg₃N₂) as expected, this being the lowest energy nitride reaction. Peaks for polyaniline (PANI) are also present with a variety of oxide peaks. Peaks associated with MgOₓN_{y} are also apparent indicating that some MgO is converted in the PEO arc.

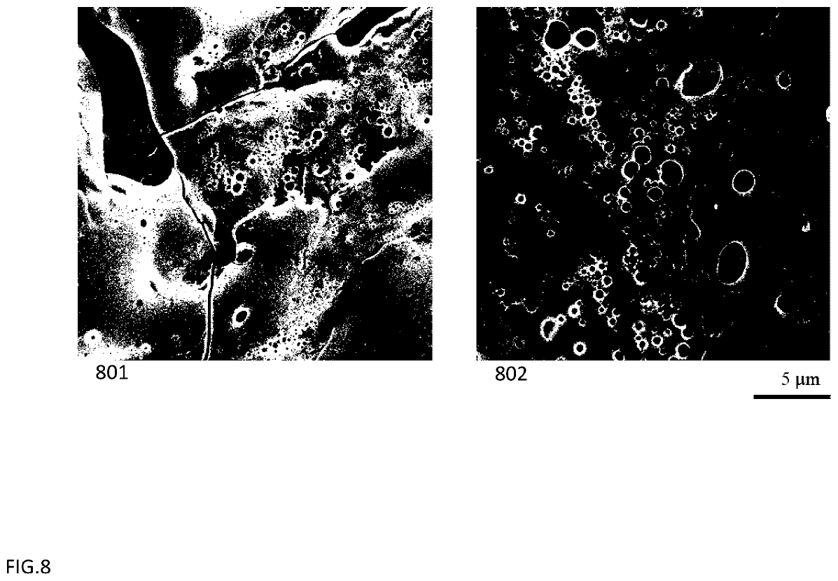

FIG. 8 shows examples of coated Al substrate. 801 is produced according to certain aspects of this disclosure from an identical method to that of coating in FIG. 3. 802 is an example of coated Al substrate produced via an identical method to that of the coating in FIG. 4. The SEM images in 801 and 802 show the distinction in morphologies between the Al6061 alloys treated in PEO baths without and with the conductive polymer component, aniline, respectively. The Al6061 alloy treated in the aniline containing PEO bath shows more uniform morphology and pore distribution. The surface cracks, observed in 801, are less prominent on the aniline-treated coating.

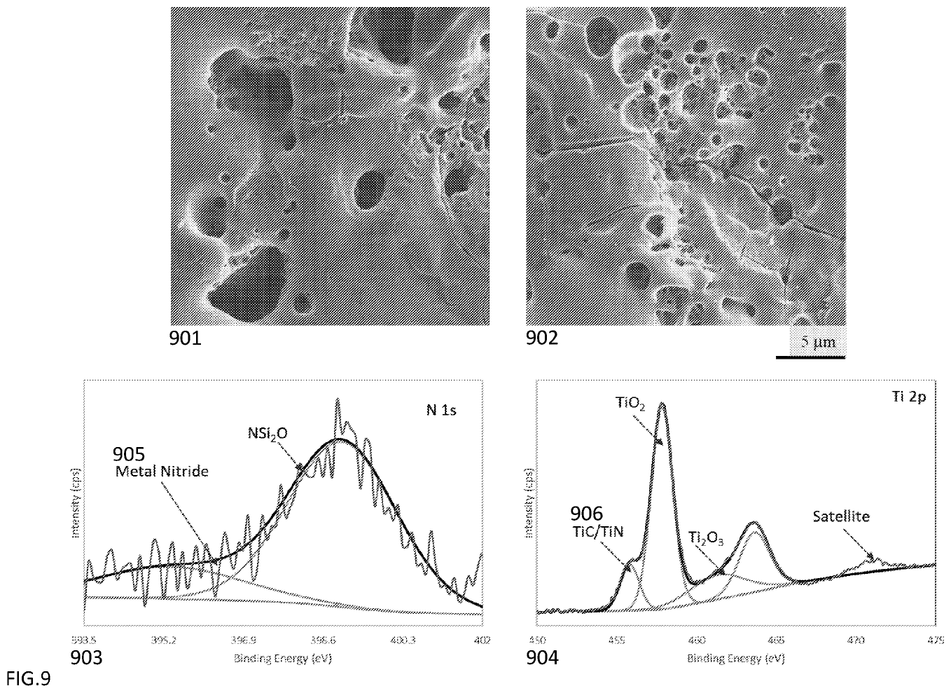

FIG. 9 shows examples of coated Ti substrates. The SEM images in 901 and 902 are of Ti substrates treated using PEO baths without and with the conductive polymer component, aniline, respectively. 901 is produced from an identical method to that of the coating in FIG. 3. 902 is an example of coated Ti substrate produced using an identical method to that of the coating in FIG. 4. The coating in 901 exhibits pores and morphology typical of a PEO treated Ti substrate. The coating in image 902 shows that treating Ti substrates using a PEO bath with aniline increased the uniformity in pore distribution. The treatment using an aniline containing bath also introduced stress-induced surface cracks which are absent from the coating in 901.

FIGS. 9, 903 and 904 show XPS spectra collected for N 1s and Ti 2p from the coating in 902. The peak analysis shows that PEO treatment in aniline-containing electrolyte aided the development of nitride (905) and carbide (906) contents in the coating.

The presence of nitrides and carbides in the coating is unexpected as the formation of these compounds is typically a high temperature reaction as shown in the equations below:

$$3 Mg + {N}_{2} {\to }^{780 - 800 ° C .} {Mg}_{3} {N}_{2} \qquad ( 1 )$$

$$3 Si + 2 {N}_{2} {\to }^{1200 - 1500 ° C .} {Si}_{3} {N}_{4} \qquad ( 2 )$$

$$3 Al + {N}_{2} {\to }^{800 - 1200 ° C .} 2 AlN \qquad ( 3 )$$

$$2 Ti + {N}_{2} {\to }^{∼ 800 ° C .} 2 TiN \qquad ( 4 )$$

$$Ti + C {\to }^{∼ 1050 ° C .} TiC \qquad ( 5 )$$

The formation of the nitrides or carbides is understood to proceed initially by the anodic electrochemical deposition of aniline on the Mg/Al/Ti or MgO/AlO//Ti-O surface. The localised high energy of the micro arc discharges is sufficient to strip the nitrogen or carbon from the developing polyaniline and combine it with the metals to create the observed nitrides and carbides. Mg₃N₂ is the predominant nitride as this is the reaction requires the lowest temperature. The Mg(OH)₂ peaks detected are assumed to develop from the hydration of the Mg₃N₂. TiN, TiC, AlN and AlC are assumed to develop in a similar manner on the PEO-treated Ti and Al substrates.

As may be seen in the SEM/EDS analysis 402 of FIG. 4, very little conductive polymer remains in the coating as indicated by the low level of carbon in the EDS analysis.

### EXAMPLES

The following examples point out specific operating conditions and illustrate the practice of the disclosure. However, these examples are not to be considered as limiting the scope of the disclosure. The examples are selected to specifically illustrate aspects of the PEO bath development, the features of the metallic interlock layer, and the production of a coating stack-up providing good corrosion protection to the magnesium substrate.

### Example 1—First Optimisation of the Process for Magnesium with Aniline

A design of experiment (DOE) process was adopted to produce a first level of coating optimisation and is described here. The DOE proceeded in two phases, the first DOE, a two-level analysis, looked at bath chemistry and PEO parameters to coarsely optimise the process.

In executing the first DOE three qualification conditions were considered, these were: appearance; energy consumption and coating Open Circuit Potential (OCP)—as a stand-in for corrosion performance. Table 1 shows the conditions for the DOE and results of the DOE. It will be noted that the experiment includes analysis of the interrelationship between factors. The appearance score was determined subjectively and scored 1-16 (with 16 being the preferred appearance score), while the other factors were determined objectively.

TABLE 1

| | | | | 4 | | | | 8 | | | 11 | | | | | Results | | |
|---|---|---|---|---|---|---|---|---|---|---|---|---|---|---|---|---|---|---|
| | 1 | 2 | | C | | | 7 | D | | | F | | 13 | 14 | | | | EC |
| | A | B | | Sodium | | | E | Ani- | | | Cur- | | G | H | | Appear- | | (A · |
| Tri- | NaOH | Na₂SiO₃ | 3 | Citrate | 5 | 6 | H₂O₂ | line | 9 | 10 | rent | 12 | SDS | Time | 15 | ance | OCP | min · |
| al | g/L | g/L | A*B | g//L | A*C | B*C | mL/L | mL/L | A*D | B*D | (A) | C*D | mM | (min) | Blank | Score | (V) | V) |
| 1 | 35 | 30 | 1 | 12 | 1 | 1 | 0.6 | 1.8 | 1 | 1 | 0.06 | 1 | 0.5 | 7.5 | 1 | 9 | −1.611 | 40.5 |
| 2 | 35 | 30 | 1 | 12 | 1 | 1 | 0.6 | 3.7 | 2 | 2 | 0.12 | 2 | 1.0 | 15 | 2 | 1 | −1.587 | 194.4 |
| 3 | 35 | 30 | 1 | 24 | 2 | 2 | 1.2 | 3.7 | 1 | 1 | 0.06 | 2 | 1.0 | 15 | 2 | 7 | −1.599 | 101.7 |
| 4 | 35 | 30 | 1 | 24 | 2 | 2 | 1.2 | 1.8 | 2 | 2 | 0.12 | 1 | 0.5 | 7.5 | 1 | 8 | −1.577 | 98.1 |
| 5 | 35 | 60 | 2 | 12 | 1 | 2 | 1.2 | 1.8 | 1 | 2 | 0.12 | 1 | 0.5 | 15 | 2 | 13 | −1.586 | 165.6 |
| 6 | 35 | 60 | 2 | 12 | 1 | 2 | 1.2 | 3.7 | 2 | 1 | 0.06 | 2 | 1.0 | 7.5 | 1 | 16 | −1.58 | 37.8 |
| 7 | 35 | 60 | 2 | 24 | 2 | 1 | 0.6 | 3.7 | 1 | 2 | 0.12 | 2 | 1.0 | 7.5 | 1 | 11 | −1.578 | 87.3 |
| 8 | 35 | 60 | 2 | 24 | 2 | 1 | 0.6 | 1.8 | 2 | 1 | 0.06 | 1 | 0.5 | 15 | 2 | 10 | 1.574 | 88.2 |
| 9 | 70 | 30 | 2 | 12 | 2 | 1 | 1.2 | 3.7 | 2 | 1 | 0.12 | 1 | 1.0 | 7.5 | 2 | 6 | −1.625 | 60.3 |
| 10 | 70 | 30 | 2 | 12 | 2 | 1 | 1.2 | 1.8 | 1 | 2 | 0.06 | 2 | 0.5 | 15 | 1 | 5 | −1.622 | 60.3 |
| 11 | 70 | 30 | 2 | 24 | 1 | 2 | 0.6 | 1.8 | 2 | 1 | 0.12 | 2 | 0.5 | 15 | 1 | 4 | −1.6 | 156.6 |
| 12 | 70 | 30 | 2 | 24 | 1 | 2 | 0.6 | 3.7 | 1 | 2 | 0.06 | 1 | 1.0 | 7.5 | 2 | 12 | −1.597 | 33.3 |
| 13 | 70 | 60 | 1 | 12 | 2 | 2 | 0.6 | 3.7 | 2 | 2 | 0.06 | 1 | 1.0 | 15 | 1 | 3 | −1.581 | 59.4 |
| 14 | 70 | 60 | 1 | 12 | 2 | 2 | 0.6 | 1.8 | 1 | 1 | 0.12 | 2 | 0.5 | 7.5 | 2 | 2 | −1.616 | 58.5 |
| 15 | 70 | 60 | 1 | 24 | 1 | 1 | 1.2 | 1.8 | 2 | 2 | 0.06 | 2 | 0.5 | 7.5 | 2 | 15 | −1.618 | 29.7 |
| 16 | 70 | 60 | 1 | 24 | 1 | 1 | 1.2 | 3.7 | 1 | 1 | 0.12 | 1 | 1.0 | 15 | 1 | 14 | −1.576 | 145.8 |

For each experiment, a fresh 200 mL PEO solution was prepared; the concentrations of chemicals are expressed in g/L, mL/L, or mMol as indicated in Table 1. The bath temperature was held constant at 25° C. and the bath was agitated at 600 rpm using a magnetic stirring bar. The counter electrode was a stainless-steel plate.

Samples were 2 cm×3 cm AZ80 magnesium coupons 1 cm thick. The coupons were mechanically ground to 800 grit, drilled for anode connection with a 2 mm insulated Al wire. The hole and wire were sealed with epoxy around the connection entry point.

The OCP was measured in a two-electrode cell over a period of 10 minutes to observe the changes.

Energy was determined by multiplying the average voltage multiplied by the established current. The voltage information was recorded by a data logger every 5 seconds.

FIG. 6 shows selected results from the DOE, looking at sample T6, which provided the optimum performance. 601 shows a voltage PEO processing curve for the sample T6, here the point marked “A” represents the end of first PEO processing region during which the initial oxide layer becomes continuous and arcing commencing. The point “B” is the end of second PEO processing region at which the initial of low intensity arcing process completes. When comparing T6 with other samples in the experiment, the voltage between A and B is quite stable over a longer period, which indicates that a quality PEO film is forming.

FIG. 6, graph 602, shows a chart of the sample OCP plated against a DOE variable which represents a combination of energy consumption, bath chemical concentration and appearance. Here the point labelled ‘T6’ is a simultaneously the lowest OCP and the lowest of the artificial DOE parameter. 603 is an OCP time curve for this sample, (unlike other samples) the OCP is relatively stable over time, the initial dip perhaps is a porous point in the coating which passivates with time.

Image 604 in FIG. 6 is a 200x optical image of the surface showing the uniform nature of the coating.

### Example 2—Second Optimisation of the Process for Magnesium (Mg) with Aniline

A second DOE was performed to further optimise the coating performance. This process was a three-level analysis, centred on the parameters for sample “T6” further optimising the process. The parameters investigated and the results obtained are listed in Table 2. In this experiment the following parameters were constant: SDS and sodium citrate 24 mL/L, SDS 0.05 mMol, current density at 1 A/dm², bath temperature at 25° C., PEO processing time of 15 minutes, and agitation with 600 rpm magnetic stirring.

TABLE 2

| | ml/200 ml | | | | Results | |
|---|---|---|---|---|---|---|
| Trial | NaOH | Na₂SiO₃ | Aniline | H₂O₂ | Dipping | OCP |
| 1 | 25 | 50 | 2.5 | 1.2 | 7 | −1.541 |
| 2 | 25 | 60 | 3.7 | 1.8 | 8 | −1.507 |
| 3 | 25 | 70 | 4.9 | 2.4 | 9 | −1.511 |
| 4 | 35 | 50 | 3.7 | 2.4 | 6 | −1.515 |
| 5 | 35 | 60 | 4.9 | 1.2 | 1 | −1.495 |
| 6 | 35 | 70 | 2.5 | 1.8 | 4 | −1.527 |
| 7 | 45 | 50 | 4.9 | 1.8 | 2 | −1.510 |
| 8 | 45 | 60 | 2.5 | 2.4 | 3 | −1.523 |
| 9 | 45 | 70 | 3.7 | 1.2 | 5 | −1.505 |

The results evaluated were OCP and corrosion protection. OCP was analytically measured. The corrosion was subjectively measured as the time to pitting with a sample dipped in a 5 wt.% NaCI solution. Sample 5 was best with no pitting after 5 hours.

As may be observed by further refining the bath composition and process the OCP was significantly reduced from the first experiment.

### Example 3 Process for Aluminium (Al) with Aniline

A simple experiment was performed to validate the ability for the process to deposit micro arc developed nitride surfaces on Al substrates from an alkaline anodizing bath.

A 2 cm×3 cm 6061 substrate was degreased and polished.

A PEO bath containing 45 g/L NaOH, 60 g/L Na₂SiO₃, 24 g/L sodium citrate, 6 mL/L of hydrogen peroxide, 4.9 ml/L aniline, and 0.05 mmol/L SDS was prepared freshly for each sample.

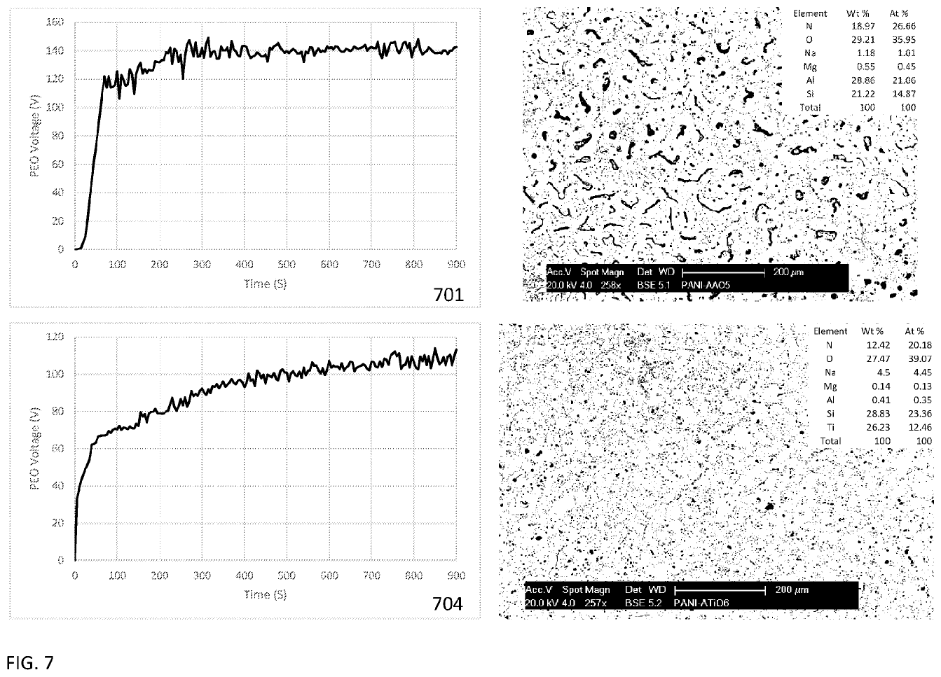

PEO was performed at a constant current of 4 A/dm², for 15 minutes. FIG. 7, 701 shows the voltage time curve for the anodizing process, clearly showing the similarities to the magnesium PEO process.

FIG. 7, 702 shows an SEM image and 703, a SEM/EDS analysis of the coating showing the presence of nitrogen in the coating, together with Si, Na, Mg, Al, and O. The level of Si suggests that most of the coating comprises aluminium silicates and aluminium oxides. The nitrides are of aluminium.

### Example 4 Process for Titanium (Ti) with Aniline

A simple experiment was also performed to validate the ability for the process to deposit micro arc developed nitride containing surfaces on Ti substrates from an alkaline PEO bath

A 1 cm×3 cm Ti substrate was polished and degreased.

A PEO bath containing 45 g/L NaOH, 60 g/L Na₂SiO₃, 24 g/L sodium citrate, 6 mL/L of hydrogen peroxide, 4.9 ml/L aniline, and 0.05 mmol/L SDS was prepared freshly for each sample.

PEO was performed at a constant current of 4 A/dm², for 15 minutes. FIG. 7, 704 shows the voltage time curve for the PEO process, clearly showing the similarities to the magnesium PEO process.

FIG. 7, 705 shows an SEM image and 706, a SEM/EDS analysis of the coating showing the presence of nitrogen in the coating, together with Si, Na, Ca, Mg, Al, Ti and O. The level of Si suggests that most of the coating comprises titanium silicates and titanium oxides. The nitrides are of titanium.

The XPS spectra in FIGS. 9, 903 & 904, for PEO-treated Ti substrate (FIG. 9, 902) indicate the presence of carbides and nitrides of Ti in the coating. The results suggest that addition of aniline to the PEO bath chemistry aided in the development of titanium carbide and titanium nitride in the coating.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

1. A method, comprising the steps of:
placing a substrate into a controlled conductivity plasma electrolytic oxidation (PEO) bath configured for the substrate; wherein the PEO bath includes a nitrogen containing organic compound, and
applying a voltage for a period of time to produce a substantially continuous nitride or nitrogen compound containing PEO layer of about 1 to 100 microns thick on the substrate.

2. The method as claimed in claim 1, wherein the voltage applied is less than about 160 volts.

3. The method as claimed in claim 1 or claim 2, wherein the period of time the voltage is applied is at least about 100 seconds.

4. The method as claimed in any one of claims 1 to 3, wherein the PEO bath is an alkaline PEO bath having a pH above 8.

5. The method as claimed in any one of claims 1 to 4, wherein the nitrogen containing organic compound is a primary, secondary or tertiary amine.

6. The method as claimed in any one of claims 1 to 5, wherein the nitrogen containing organic compound is a monomer that upon polymerisation forms a nitrogen containing conductive polymer.

7. The method as claimed in claim 5 or claim 6, wherein the nitrogen containing organic compound can be selected from aniline, pyrrole, triethylamine or combinations thereof.

8. The method of any one of claims 1 to 7, wherein the nitrogen containing organic compound can be aniline.

9. The method of any one of claims 1 to 8, wherein the substrate is a magnesium substrate, a titanium substrate, or an aluminium substrate.

10. The method of any one of claims 1 to 9, wherein the PEO bath includes between about 5-80 g/L of at least one of sodium hydroxide or potassium hydroxide.

11. The method of any one of claims 1 to 10, wherein the PEO bath further includes between about 10-90 g/L of disodium metasilicate.

12. The method of any one of claims 1 to 11, wherein the PEO bath further includes between about 1-40 g/L of sodium citrate.

13. The method of any one of claims 1 to 12, wherein the PEO bath further includes between about 2-30 ml/L of hydrogen peroxide.

14. The method of any one of claims 1 to 13, wherein the PEO bath further includes between about 0.1 M and 1 M of a monomer that upon polymerisation forms a nitrogen containing conductive polymer or between about 0.1 M and 1 M of a nitrogen containing organic compound.

15. The method of any one of claims 1 to 14, wherein the PEO bath further includes between about 0.1 mM to 1 M of a surfactant.

16. The method of any one of claims 1 to 15, further including a substrate pre-treatment step.

17. The method of any one of claims 1 to 16, wherein the PEO bath is maintained at room temperature.

18. A method, comprising the steps of:
pre-treating a magnesium, titanium or aluminium substrate;
cleaning the substrate with de-ionized water;
placing the substrate into a controlled conductivity PEO bath configured for the substrate;
wherein the PEO bath includes a nitrogen containing organic compound, and
applying a voltage for a period of time to produce a substantially continuous nitride or nitrogen compound containing PEO layer of about 1 to about 100 microns thick on the substrate.

19. The method of claim 18, wherein the pre-treating step comprises at least one of:
treating the substrate in an acid bath, mechanically roughening the substrate, or cleaning the substrate in an alkaline bath.

20. The method of claim 18 or claim 19, wherein the PEO bath includes between about 5-80 g/L of at least one of sodium hydroxide or potassium hydroxide.

21. The method of any one of claims 18 to 20, wherein the PEO bath further includes between about 10-90 g/L of disodium metasilicate.

22. The method of any one of claims 18 to 21, wherein the PEO bath further includes between about 1-40 g/L of sodium citrate.

23. The method of any one of claims 18 to 22, wherein the PEO bath further includes between about 2-30 ml/L of hydrogen peroxide.

24. The method of any one of claims 18 to 23, wherein the PEO bath further includes between about 0.1 M and 1 M of a monomer that upon polymerisation forms a nitrogen containing conductive polymer or between about 0.1 M and 1 M of a nitrogen containing organic compound.

25. The method of any one of claims 18 to 24, wherein the PEO bath further includes between about 0.1 mM to 1 M of a surfactant.

26. The method of any one of claims 18 to 25, wherein the voltage has a peak voltage less than about 160 volts.

27. The method of any one of claims 18 to 26 wherein the conductivity of the PEO bath is controlled to limit any micro arc generation voltage during PEO processing below about 160V at a current density of less than about 10 A/dm².

28. A PEO coated substrate produced according to the method as claimed in any one of claims 1 to 27, the PEO coated substrate comprising a substantially continuous nitride containing layer of between about 1 to 100 microns thick.

29. A PEO coated substrate having a substantially continuous nitride or nitrogen compound containing layer of between about 1 to 100 microns thick, wherein the substantially continuous nitride containing layer has been formed during PEO process at a voltage below about 160V and at a current density of less than about 10 A/dm².

30. The PEO coated substrate of claim 29, wherein the substrate is aluminium, titanium or magnesium.

31. A method, comprising the steps of:
placing a substrate into a controlled conductivity, alkaline, PEO bath configured for the substrate; wherein the PEO bath includes a nitrogen containing organic compound, and
applying a voltage for a period of time to produce an PEO layer of about 1 to 100 microns thick on the substrate.

32. The method as claimed in claim 31, wherein the voltage applied is less than about 160 volts.

33. The method as claimed in claim 31 or claim 32, wherein the period of time the voltage is applied is at least about 100 seconds.

34. The method as claimed in any one of claims 31 to 33, wherein the alkaline PEO bath has a pH above 8.

35. The method as claimed in any one of claims 31 to 34, wherein the nitrogen containing organic compound is a monomer that upon polymerisation forms a nitrogen containing conductive polymer.

36. The method as claimed in any one of claims 31 to 35, wherein the nitrogen containing organic compound is a primary, secondary or tertiary amine.

37. The method as claimed in claim 35 or claim 36, wherein the nitrogen containing organic compound is selected from aniline, pyrrole, triethylamine or combinations thereof.

38. The method of any one of claims 31 to 37, wherein the nitrogen containing organic compound is aniline.

39. The method of any one of claims 31 to 38, wherein the substrate is a magnesium substrate, a titanium substrate or an aluminium substrate.

40. The method of any one of claims 31 to 39, wherein the PEO bath includes between about 5-80 g/L of at least one of sodium hydroxide or potassium hydroxide.

41. The method of any one of claims 31 to 40, wherein the PEO bath further includes between about 10-90 g/L of disodium metasilicate.

42. The method of any one of claims 31 to 41, wherein the PEO bath further includes between about 1-40 g/L of sodium citrate.

43. The method of any one of claims 31 to 42, wherein the PEO bath further includes between about 2-30 ml/L of hydrogen peroxide. 44 The method of any one of claims 31 to 43, wherein the PEO bath further includes between about 0.1 M and 1 M of a monomer that upon polymerisation forms a nitrogen containing conductive polymer or between about 0.1 M and 1 M of a nitrogen containing organic compound.

45. The method of any one of claims 31 to 44, wherein the PEO bath further includes between about 0.1 mM to 1 M of a surfactant.

46. The method of any one of claims 31 to 45, further including a substrate pre-treatment step.

47. The method of any one of claims 31 to 46, wherein the PEO bath is maintained at room temperature.

48. A method, comprising the steps of:
pre-treating a magnesium, titanium or aluminium substrate;
cleaning the substrate with de-ionized water;
placing the substrate into a controlled conductivity, alkaline, PEO bath configured for the substrate; wherein the anodizing bath includes a nitrogen containing organic compound, and
applying a voltage for a period of time to produce an PEO layer of about 1 to about 100 microns thick on the substrate.

49. The method of claim 48, wherein the pre-treating step comprises at least one of:
treating the substrate in an acid bath, mechanically roughening the substrate, or cleaning the substrate in an alkaline bath.

50. The method of claim 48 or claim 49, wherein the PEO bath includes between about 5-80 g/L of at least one of sodium hydroxide or potassium hydroxide.

51. The method of any one of claims 48 to 50, wherein the PEO bath further includes between about 10-90 g/L of disodium metasilicate.

52. The method of any one of claims 48 to 51, wherein the PEO bath further includes between about 1-40 g/L of sodium citrate.

53. The method of any one of claims 48 to 52, wherein the PEO bath further includes between about 2-30 ml/L of hydrogen peroxide.

54. The method of any one of claims 48 to 53, wherein the PEO bath further includes between about 0.1 M and 1 M of a monomer that upon polymerisation forms a nitrogen containing conductive polymer or between about 0.1 M and 1 M of a nitrogen containing organic compound.

55. The method of any one of claims 48 to 54, wherein the PEO bath further includes between about 0.1 mM to 1 M of a surfactant.

56. The method of any one of claims 48 to 55, wherein the voltage has a peak voltage less than about 160 volts.

57. The method of any one of claims 48 to 56 wherein the conductivity of the PEO bath is controlled to limit any micro arc generation voltage during PEO processing below about 160V at a current density of less than about 10 A/dm².

58. An anodized substrate produced according to the method as claimed in any one of claims 31 to 57, the anodized substrate comprising a substantially continuous nitride containing layer of between about 1 to 100 microns thick.
